(19) United States
(12) Patent Application Publication
(10) Pub. No.: US 2005/0255669 A1
(43) Pub. Date: Nov. 17, 2005

(54) Semiconductor device including isolation trench and method for fabricating the same

(76) Inventors: Sung-taeg Kang, Seoul (KR); Jeong-uk Han, Suwon-si (KR); Sung-woo Park, Gunpo-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/095,569

(22) Filed: Apr. 1, 2005

(30) Foreign Application Priority Data
May 11, 2004 (KR) 2004-33070

(51) Int. Cl. H01L 21/76

(52) U.S. Cl. 438/437

(57) ABSTRACT

Provided is a trench isolation for a semiconductor device. The device includes an insulating layer formed on the inner surface of a trench and includes at least an N-containing CVD oxide layer, and a nitride liner formed on the insulating layer.

### BACKGROUND OF THE INVENTION

1. Field of the Invention

The present invention generally relates to a semiconductor device and a method for fabricating the same. More particularly, the present invention generally relates to a semiconductor device having an isolation trench, and a method for fabricating the same.

A claim of priority is made to Korean Patent Application No. 2004-33070, filed on May 11, 2004, the disclosure of which is incorporated herein.

2. Description of the Related Art

The integration density of semiconductor devices has recently improved along with developments in semiconductor technologies. However, there is an increasing need for smaller, finer patterns in the semiconductor devices. These tendencies also apply to isolation layers, which occupy wide areas in a semiconductor device.

Conventional semiconductor devices generally employ a local oxidation of silicon (LOCOS) oxide layer for isolation purposes. However, the manufacturing of the LOCOS oxide layer leads to a bird's beak, which reduces the area in an active region, and also causes a leakage current.

Currently, an isolation trench with its narrow and excellent isolation characteristics has been used for isolation purposes.

FIG. 1 is a cross sectional view of a conventional an isolation trench.

In a semiconductor substrate 10, a trench 16 is formed to a predetermined depth. However, a dry etch process used to form trench 16 may cause silicon lattice defects and damage to the inner surface of trench 16. To reduce the silicon lattice defects and other damages, a second oxide layer 18 is formed on the inner surface of trench 16. Second oxide layer 18 is formed to a thickness of “d,” which is about 50 to 100 Å. Thereafter, a nitride liner 20 is formed on second oxide layer 18. Trench 16 is filled with an insulating material, such as a high density plasma (HDP) oxide 22, to complete an isolation trench 25. Nitride liner 20 prevents further oxidization of sidewall 18 and improves the insulating properties of isolation trench 25.

However, it is difficult to uniformly form second oxide layer 18 because of the following problems. First, a case where the thickness of second oxide layer 18 is too thin will be described.

A silicon nitride layer has excellent charge trapping characteristics, thus is typically used as a charge trapping device in nonvolatile memory devices. Hot carriers in a highly integrated semiconductor MOS transistor typically have high energy; these hot carriers are prone to jump into a thin gate oxide layer 32, or the hot carriers move through second oxide layer 18 and get trapped by nitride liner 20. Most of the hot carriers trapped by nitride liner 20 are negative charges, i.e., electrons 50.

As electrons 50 agglomerate, positive charges, i.e., holes 52, accumulate around isolation trench 25. Holes 52 function as a conducting path, and joins junction regions 40a and 40b. Junction regions 40a and 40b are segregated from each other by isolation trench 25. Thus, a leakage current flows through substrate 10. Also, electrons 50 may form a conducting path at the edge of isolation trench 25 and create another leakage current. Here, a gate electrode 38 includes a first gate electrode 34 on an active region and a second gate electrode 36 on isolation trench 25.

FIG. 2 shows a measured value of threshold voltage Vₜₕ obtained using charge pumping, and FIG. 3 is a graph showing the variation of threshold voltage Vₜₕ with respect to the number of times a pulse voltage is applied to gate electrode 38.

Referring to FIG. 2, charge pumping is performed by applying a pulse voltage to gate electrode 38 and maintaining substrate 10 at a reference voltage of 0 V. A leakage current flowing through substrate 10 is measured in an inversion state and an accumulation state between source and drain regions in accordance with the variation of a pulse voltage. In other words, charge pumping measures the interfacial state of gate oxide layer 32. When charges are trapped in gate oxide layer 32, the leakage current from the source and drain increases. In other words, the current due to the accumulated electrons increases in a negative (−) current direction. Accordingly, when the charges are trapped in gate oxide layer 32, the threshold voltage Vₜₕ decreases. In particular, the threshold voltage Vₜₕ is greatly affected if the semiconductor device is a PMOS.

Referring to FIG. 3, the number of times a pulse voltage is applied to gate electrode 38 is greater in the upper portion of the curve than the lower portion of the curve. As the number of times the pulse voltage is applied to gate electrode 38 increases, the number of electrons trapped in the layer of isolation trench 25 increases. An increase in the number of electrons affects the threshold voltage, thus creating a hump “a” before reaching a standard-state threshold voltage.

The case where the thickness of the second oxide layer 18 is too thick will be described with reference to FIG. 4. FIG. 4 shows the concentration of boron (B) versus the distance between isolation trench 25 and substrate 10. If second oxide layer 18 is too thick, local stress induced defects are produced in substrate 10. Through these defects, boron diffuses from substrate 10 into isolation trench 25. As a result, the concentration of boron is greatly reduced near the interface between isolation trench 25 and substrate 10. Also, substrate 10 defects result in an increase in leakage current.

To solve these problems, for example, U.S. Pat. No. 6,486,517 discloses an isolation layer and a method for fabricating the same. The patent attempts to appropriately control the thickness of a sidewall oxide layer. The patent is directed to a DRAM device to which a low voltage of about 3.3 V is applied. However, the patent is not applicable to a semiconductor device to which a high voltage of 10 V or greater is applied.

U.S. Pat. No. 6,486,517 prevents charge trapping by increasing the thickness of the sidewall oxide layer; however, a high voltage device cannot prevent charge trapping in such a manner. Specifically, increasing the thickness of the sidewall oxide layer in a high voltage device causes local stress and leakage current, which seriously reduce the reliability of the high voltage device as described above.

### SUMMARY OF THE INVENTION

The present invention provides a semiconductor device including a trench isolation, which prevents charge trapping and removes stress induced defects.

The present invention also provides a method of fabricating a semiconductor device, which prevents charge trapping and removes stress induced defects.

According to an aspect of the present invention, a semiconductor device a semiconductor substrate, an isolation trench formed in the semiconductor substrate, an insulating layer formed on the inner surface of the isolation trench, wherein the insulating layer comprises a chemical vapor deposition (CVD) oxide layer containing Nitrogen, and a nitride liner formed on the insulating layer.

Provided is a method for fabricating an isolation trench for a semiconductor device by forming a trench in a selected region of a substrate, forming an insulating layer on an inner surface of the trench, wherein the insulating layer includes a chemical vapor deposition (CVD) oxide layer containing Nitrogen, forming a nitride liner on the insulating layer, and filling the trench with a filler to form the isolation trench.

Also provided is another method for fabricating an isolation trench for a semiconductor device by forming a trench in a selected region of a substrate, forming an insulating layer on an inner surface of the trench, wherein the insulating layer includes a second oxide layer and a chemical vapor deposition (CVD) oxide layer containing Nitrogen, forming a nitride liner on the insulating layer, filling the trench with a filler to form the isolation trench, forming junction regions adjacent the isolation trench, forming a gate oxide layer on the substrate, forming at least one gate electrode on the gate oxide layer and the isolation trench.

### BRIEF DESCRIPTION OF THE DRAWINGS

Exemplary embodiments of the present invention will be described with reference to the attached drawings in which:

FIG. 1 is a cross sectional view of an isolation trench in a conventional semiconductor device;

FIG. 2 is a graph showing the measured value of threshold voltage obtained using charge pumping;

FIG. 3 is a graph showing the variation of threshold voltage with respect to the number of times a pulse voltage is applied to a gate electrode;

FIG. 4 is a graph showing the concentration of boron (B) versus the distance between an isolation trench and a substrate;

FIGS. 5 through 14 are cross-sectional views illustrating a method of manufacturing the isolation trench in a semiconductor device according to the present invention;

FIG. 15 is a cross-sectional view of the isolation trench in the semiconductor device according to the present invention;

FIG. 16 is a graph comparing a leakage current of the semiconductor device manufactured according to the present invention with a leakage current of the conventional semiconductor device of FIG. 1; and

FIG. 17 is a graph showing the concentration of boron (B) versus the distance between the isolation layer and the substrate according to the present invention.

### DETAILED DESCRIPTION OF THE INVENTION

The present invention will now be described more fully with reference to the accompanying drawings, in which exemplary embodiments of the invention are shown. This invention may, however, be embodied in many different forms and should not be construed as being limited to the embodiments set forth herein. Rather, these embodiments are provided to convey working examples. It will be understood that when an element such as layer, region or substrate is referred to as being “on” or “onto” another element, the element is either directly on the other element or intervening elements may also be present.

In the present invention, a method of fabricating an isolation trench is preferably applied to fine electronic devices, such as highly integrated circuit semiconductor devices, micro electro mechanical (MEM) devices, optoelectronic devices, and display devices.

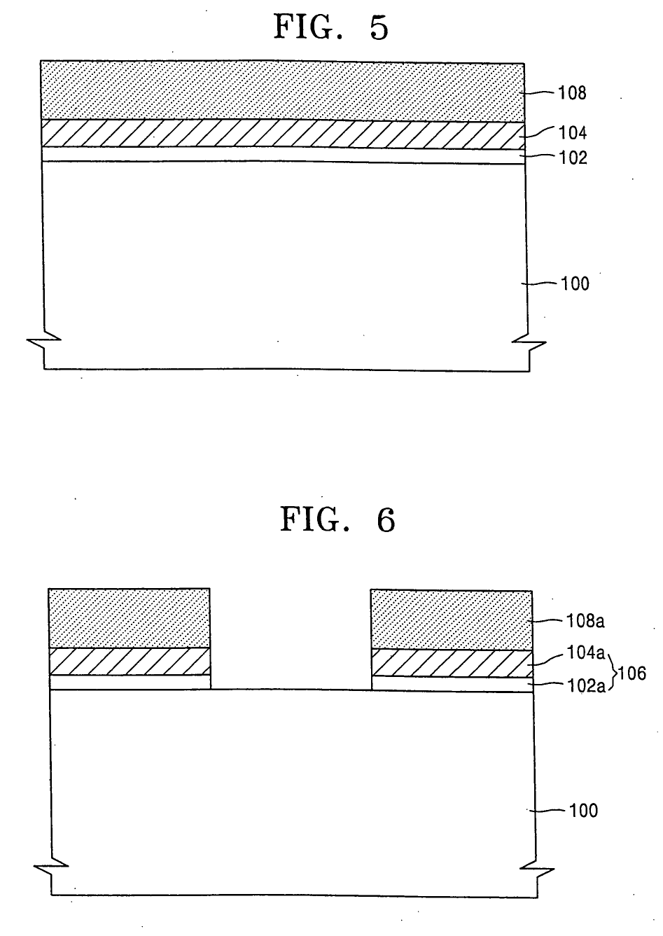

Referring to FIG. 5, a pad oxide layer 102 and a nitride layer 104 are sequentially formed on a substrate 100. Pad oxide layer 102 reduces the stress between substrate 100 and nitride layer 104, and is formed to a thickness of about 20 to 200 Å, preferably about 100 Å. Nitride layer 104 serves as a hard mask during an etch process used to form a trench, and is deposited to a thickness of about 500 to 2000 Å, preferably 800 to 850 Å. Nitride layer 104 is formed of silicon nitride and deposited using a chemical vapor deposition (CVD), sub-atmospheric CVD (SACVD), low pressure CVD (LPCVD), or plasma enhanced CVD (PECVD) process. An organic anti-reflection coating (ARC) (not shown) and a photoresist 108 are coated on nitride layer 104.

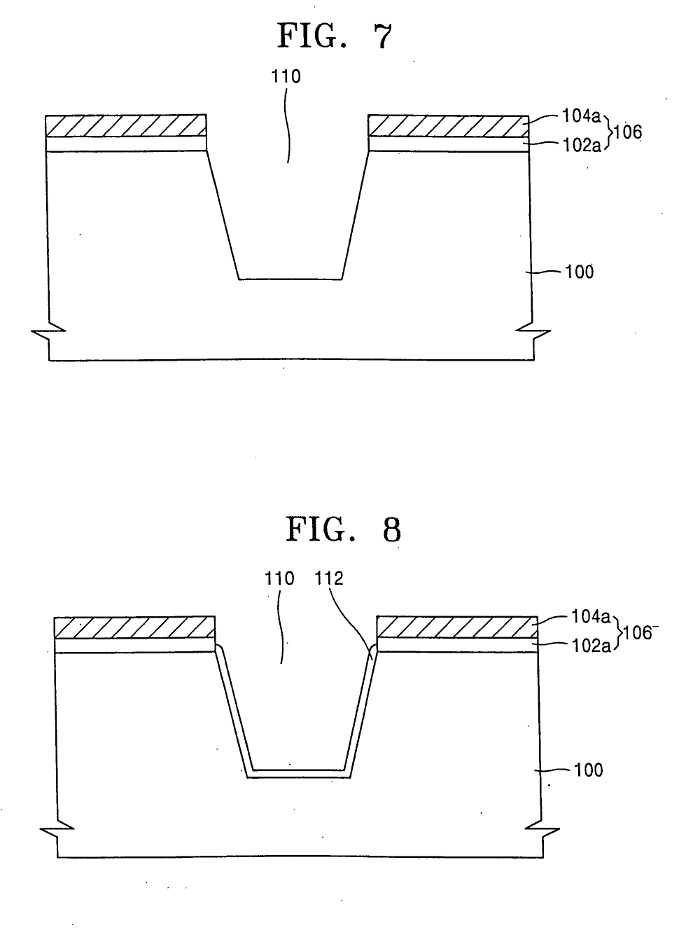

Referring to FIG. 6, a photoresist pattern 108a is formed to define an active region (not shown). Nitride layer 104 and pad oxide layer 102 are dry etched using photoresist pattern 108a as an etch mask to form a pad mask 106, which includes a nitride pattern 104a and a pad oxide pattern 102a. Nitride layer 104 is formed using a fluorocarbon gas, such as CₓF_{y} gas or CₐH_{b}F_{c} gas, for example, CF₄, CHF₃, C₂F₆, C₄F₈, CH₂F₂, CH₃F, CH₄, C₂H₂, C₄F₆, or mixture thereof. Here, Ar gas is preferably used as an atmospheric gas.

Referring to FIG. 7, photoresist pattern 108a is removed, and an exposed portion of substrate 100 is anisotropically dry etched using pad mask 106 as an etch mask to form an isolation trench region 110 defining the active region. Photoresist pattern 108a is preferably removed by an ashing process using O₂-plasma and organic stripping processes. Isolation trench region 110 is formed to a depth sufficient for isolation purposes.

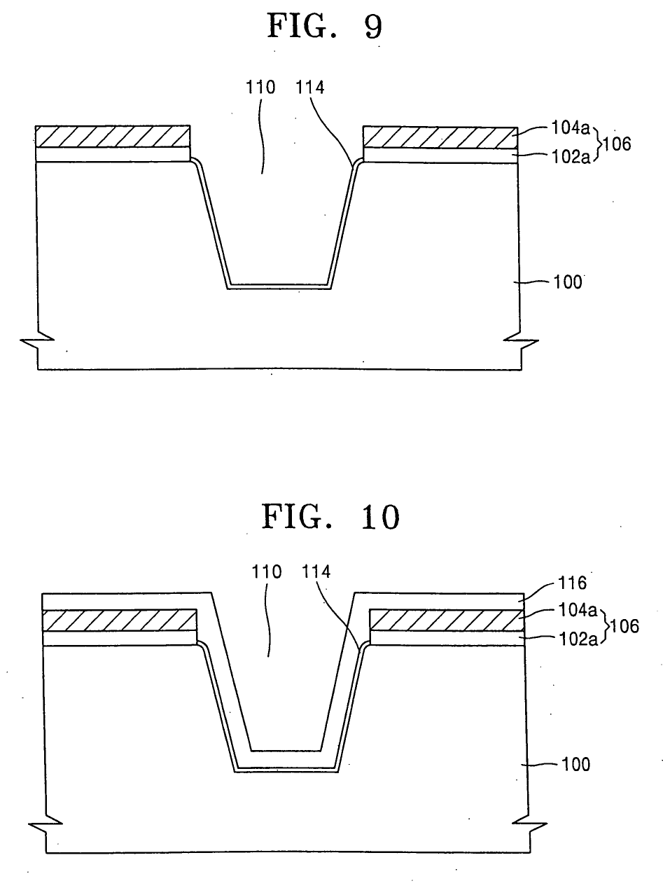

Referring to FIG. 8, a sacrificial oxide layer 112 is formed on the inner and bottom surfaces of trench 110 and the sidewalls of pad oxide pattern 102a. Sacrificial oxide layer 112 is formed to remove damages and stresses caused by the etch process during the formation of isolation trench region 110. In addition, sacrificial layer 112 aids in minimizing the thickness of a second oxide layer (114 of FIG. 9), which is formed in a subsequent process. Sacrificial layer 112 is formed by a thermal oxide process to a thickness of about 10 to 200 Å.

Referring to FIG. 9, sacrificial layer 112 is wet etched to expose the inner surface of isolation trench region 110. Then, sacrificial layer 112 is removed using diluted HF (DHF), NH₄F, or buffered oxide etchant (BOE), which is a mixture of HF and deionized water (DIW). Once sacrificial oxide layer 112 is removed, the upper portion of the inner wall of isolation trench region 110 is rounded to prevent a concentration of an electric field from forming on the upper portion of isolation trench region 110. Thereafter, a second oxide layer 114 is formed on the inner surface of isolation trench region 110 and sidewalls of pad oxide pattern 102a. Second oxide layer 114 is formed to a thickness sufficient to minimize local stress, for example, 10 to 150 Å, preferably 80 to 120 Å.

Referring to FIG. 10, an N-containing CVD oxide layer 116 is deposited on the entire surface of the resultant structure. N-containing CVD oxide layer 16 is preferably formed by an annealing process in an N-containing atmosphere at a temperature of about 800° C. The atmospheric gas is N₂, NO, N₂O, or NH₃. That is, a CVD oxide layer is formed and annealed in the N-containing atmosphere so that nitrogen is solid-dissolved in the CVD oxide layer.

Alternatively, N-containing CVD oxide layer 116 may be formed by an N-containing atmospheric gas and plasma in a process chamber. The atmospheric gas is N₂, NO, N₂O, or NH₃. That is, a CVD oxide layer is formed while plasma processing the N-containing gas, thus forming an N-containing CVD oxide layer 116.

CVD oxide layer 116 is formed to a thickness of about 80 to 350 Å, preferably 150 to 250 Å, based on the gate voltage. Here, the thickness of CVD oxide layer 116 is proportional to the gate voltage. Since CVD oxide layer 116 contains less local stress than a thermal oxide layer, the thickness of CVD oxide layer 116 may be greater than the thermal oxide layer.

Also, nitrogen in CVD oxide layer 116 combines with dangling defects to remove defects at the interfacial surface between second oxide layer 114 and CVD oxide layer 116. Also, the nitrogen diffuses into and removes vacancies in CVD oxide layer 116. Thus, defects in CVD oxide layer 116 are removed by nitrogen, preventing charge trapping caused by the defects.

An insulating layer to prevent charge trapping according to the present invention is preferably a combination layer of second oxide layer 114 and N-containing CVD oxide layer 116, sequentially stacked. The combination is formed to a thickness of about 150 to 400 Å, preferably 180 to 250 Å. If the thickness of the combination layer is less than 150 Å, prevention of charge trapping is less effective. If the thickness of the combination layer is greater than 400 Å, it becomes difficult to fill trench 110 with a filler (120 of FIG. 14).

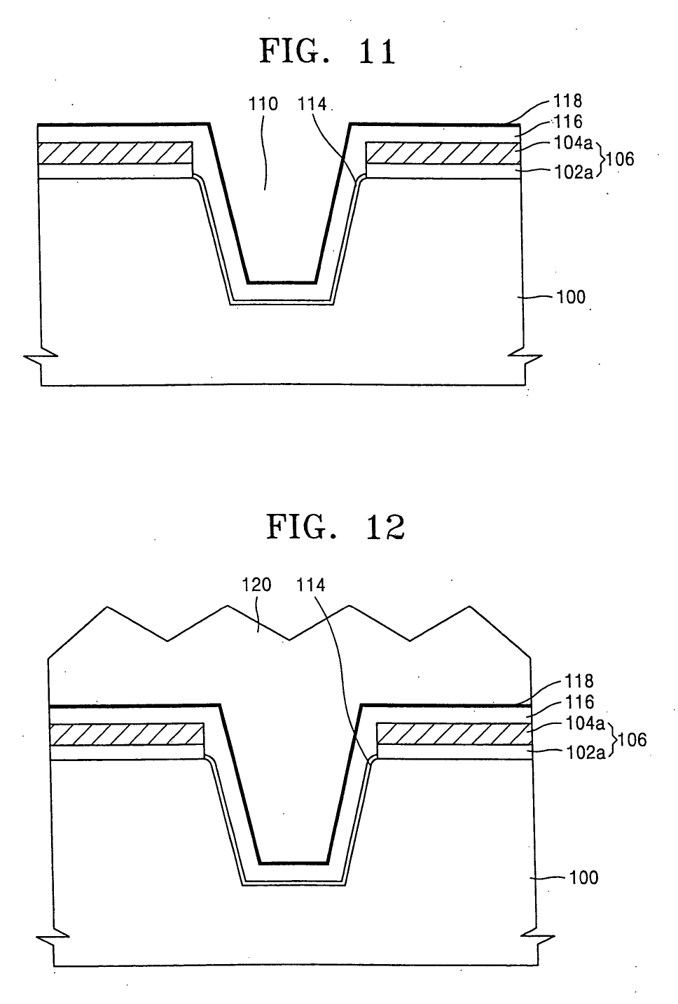

Referring to FIG. 11, a nitride liner 118 is deposited on CVD oxide layer 116. Nitride liner 118 conforms to the inner surface of isolation trench region 110. Nitride liner 118 prevents further oxidization of CVD oxide layer 120 during subsequent processes, and improves the insulation of an isolation trench (125 of FIG. 12). Nitride liner 118 is preferably formed to a thickness of about 50 to 300 Å. A capping layer (not shown) is optionally formed on nitride layer 118. The capping layer may be formed of middle temperature oxide (MTO) to prevent damage to nitride liner 118 during subsequent processes.

Referring to FIG. 12, isolation trench region 110 is filled with a filling layer 120. Filling layer 120 is an undoped silicate glass (USG), high density plasma (HDP) oxide, or TEOS formed using a PECVD process, or an oxide formed using a PECVD process. The HDP oxide is preferably used to fill isolation trench region 110. An HDP CVD process is a combination of a CVD process and an etch process using sputtering. In the HDP CVD process, a chamber is supplied with both a deposition gas to deposit a material layer, and also a sputtering gas to etch the material layer by sputtering. Accordingly, SiH₄ and O₂ are used as the deposition gases, and an inert gas (e.g., Ar gas) is used as the sputtering gas. Deposition gases and sputtering gas are ionized plasma induced by radio-frequency (RF) power in the chamber. Meanwhile, because biased RF power is applied to a wafer chuck (e.g., an electrostatic chuck (ESC)) installed in the chamber in which the substrate is loaded, the ionized deposition gases and sputtering gas are attracted toward the surface of the substrate. The accelerated ions of the deposition gases form a silicon oxide layer, while the accelerated ions of the sputtering gas sputter the deposited silicon oxide layer. As a result, by using the HDP oxide layer, filling layer 120 is densified with gap filling characteristics.

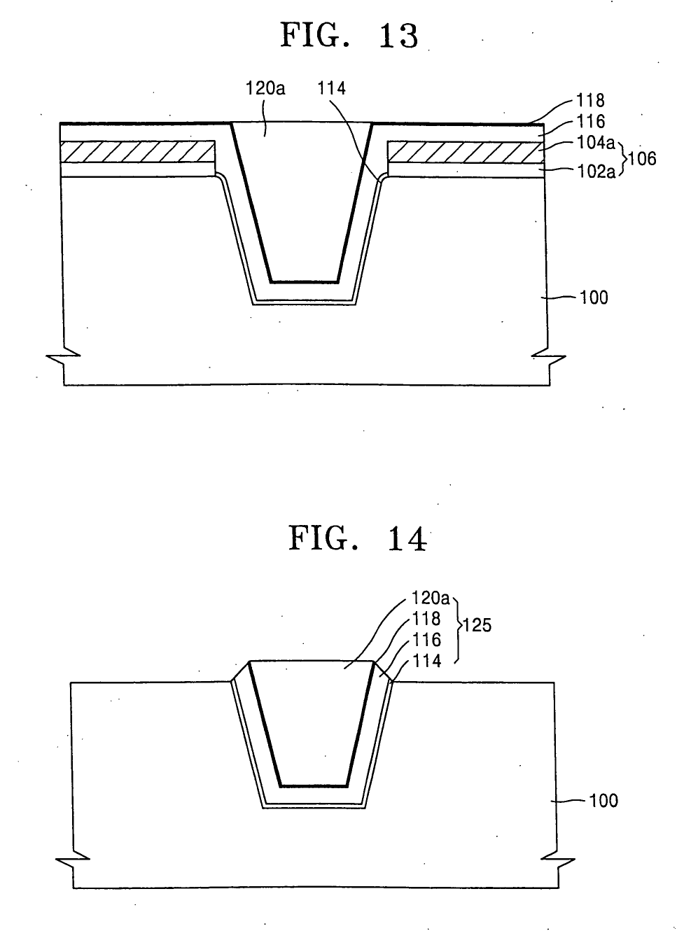

Referring to FIG. 13, filling layer 120 is planarized to form a surface substantially planar with the top of nitride liner 118. Filling layer 120 is preferably planarized using a chemical mechanical polishing (CMP) process or an etch back process. The planarization process is performed using nitride layer 118 as a planarization stop layer, for example, when HDP oxide layer 120 is planarized using CMP process, nitride liner 118 serves as a CMP stopper. The CMP process is preferably performed using a slurry, such as a ceria slurry, having a higher polishing rate with respect to H DP oxide layer 120 than nitride liner 118.

Referring to FIG. 14, nitride liner 118, CVD oxide layer 116, and pad mask 106 are removed from the top surface of the semiconductor substrate 100, thereby completing an isolation trench 125 having a filler 120a. Nitride liner 118 and nitride pattern 104a of pad mask 106 are removed using phosphoric acid (H₃PO₄), whereas CVD oxide layer 116 and pad oxide pattern 102a are removed using DHF, NH₄F, or BOE.

FIG. 15 is a cross-sectional view of an isolation trench 125 of the according to the present invention.

Referring to FIG. 15, junction regions 202a and 202b are formed in semiconductor substrate 100 and are segregated by isolation trench 125. A gate electrode 204 is formed on a gate oxide layer 202 on the active region of substrate 100 on one side of junction regions 210a and 210b. Also, a second gate electrode 206 is formed on isolation trench 125. A gate electrode 208 comprises first gate electrode 204 and second gate electrode 206.

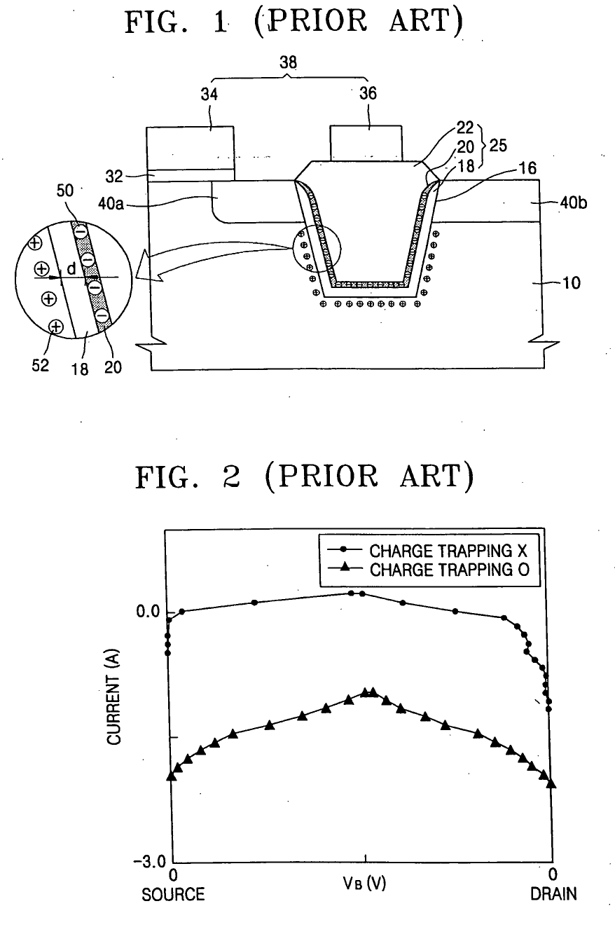

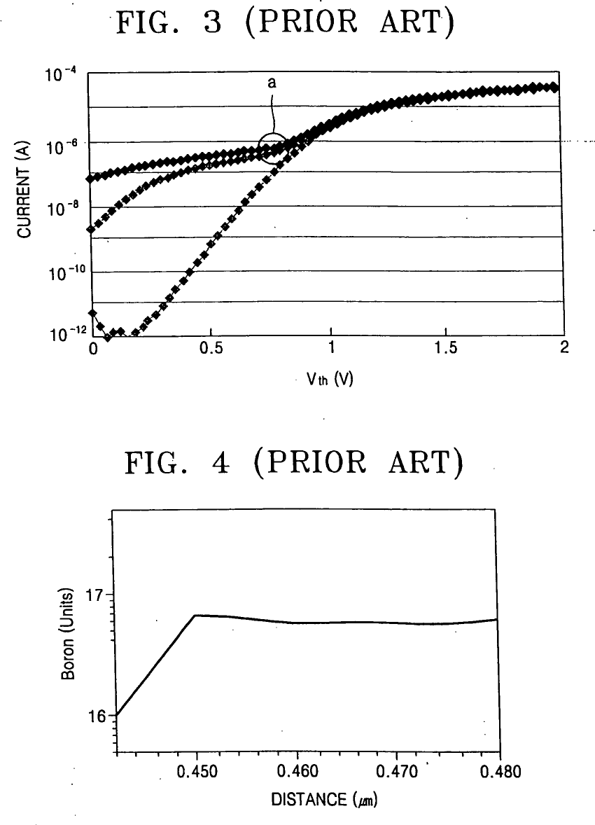

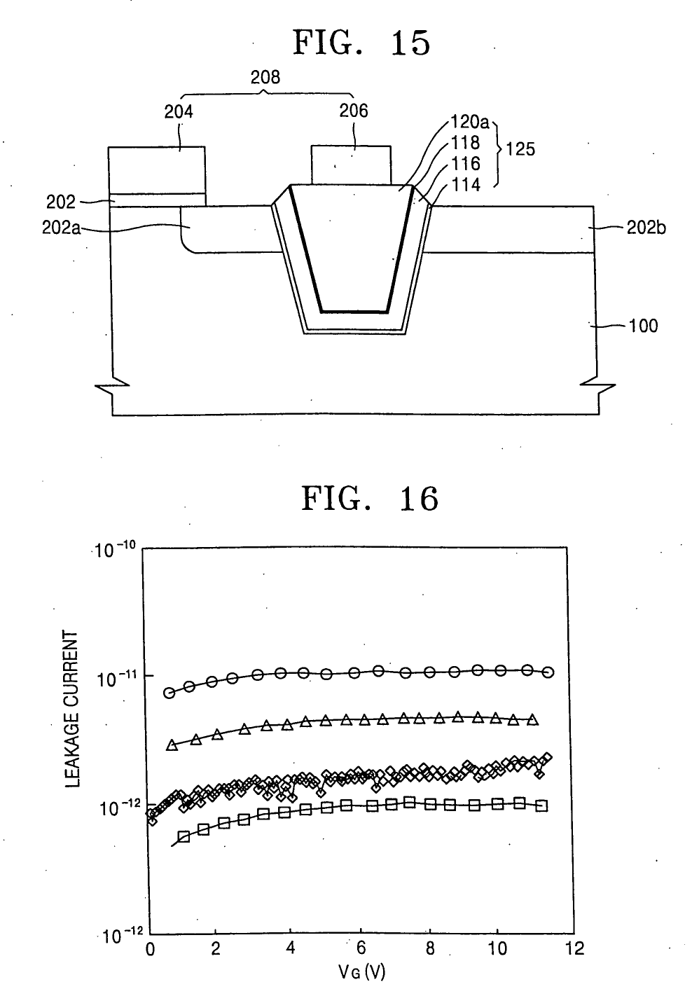

FIG. 16 is a graph comparing the leakage current of the semiconductor device according to the present invention with the leakage current of the conventional semiconductor device of FIG. 1. ◯ represents the leakage current when the second oxide layer is 200 Å; Δ represents the leakage current when the conventional isolation layer is used and an N-free CVD oxide layer is 200 Å; ⋄ represents the leakage current when N-containing CVD oxide layer 116 is 200 Å according to the present invention; and □ presents the leakage current when sacrificial oxide layer 112 is formed prior to the formation of N-containing CVD oxide layer 116.

Referring to FIG. 16, it can be seen that when N-containing CVD oxide layer 116 is included in isolation trench 125, the leakage current is significantly reduced. Noticeably, when sacrificial layer 112 is formed beforehand, the leakage current is reduced even more effectively. This is because the combination layers of second oxide layer 114 and CVD oxide layer 116 effectively prevent charge trapping and remove local stresses.

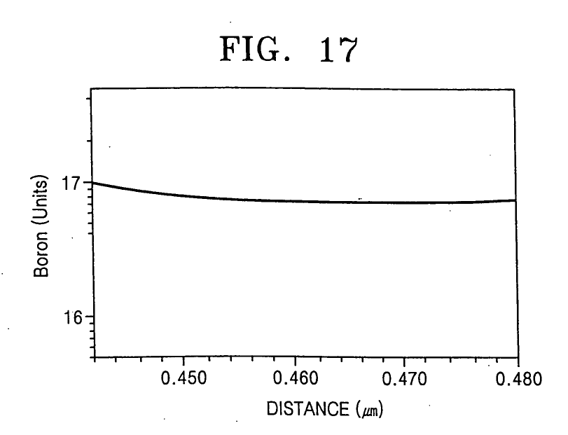

FIG. 17 is a graph showing the concentration of boron (B) versus the distance between isolation trench 125 and substrate 100 according to the present invention. In the present invention, small amounts of local stress are generated due to the thinness of sidewall oxide layer 114. Therefore, boron does not diffuse through defects on substrate 100 into isolation trench 125.

As described above, in the present invention, the N-containing CVD oxide layer is formed to a predetermined thickness on the inner surface of the trench, thereby preventing the nitride liner from trapping charges from the substrate.

Also, since the CVD oxide layer contains less local stress than a thermal oxide layer, it is possible to control its thickness to within a wide range based on the gate voltage applied to the gate electrode.

Further, since the second oxide layer is thin, few stress induced defects are generated in the substrate, preventing the diffusion of boron from the substrate into the isolation layer.

In addition, forming the sacrificial oxide layer allows the second oxide layer to be thinner and the CVD oxide layer to be formed to a sufficient thickness. This can prevent charge trapping and remove local stress. Further, when the sacrificial oxide layer is removed, the upper portion of the trench is rounded to prevent electric field concentration.

While the present invention has been particularly shown and described with reference to exemplary embodiments thereof, it will be understood by those of ordinary skill in the art that various changes in form and details may be made therein without departing from the scope of the present invention.

1. A semiconductor device, comprising:
a semiconductor substrate;
an isolation trench formed in the semiconductor substrate;
an insulating layer formed on the inner surface of the isolation trench, wherein the insulating layer comprises a chemical vapor deposition (CVD) oxide layer containing Nitrogen;
a nitride liner formed on the insulating layer; and
and a filler formed in the isolation trench.

2. The device of claim 1, wherein the insulating layer further comprises a second oxide layer located between the N-containing CVD oxide layer and the inner surface of the isolation trench.

3. The device of claim 2, further comprising:
junction regions segregated by the trench;
a gate oxide layer formed on the substrate; and
at least one gate electrode formed on the gate oxide layer and the trench.

4. The device of claim 1, wherein the insulating layer has a thickness of about 150 to 400 Å.

5. The device of claim 1, wherein the insulating layer has a thickness of about 180 to 250 Å.

6. The device of claim 1, wherein the N-containing CVD oxide layer has a thickness of about 100 to 350 Å.

7. The device of claim 2, wherein the second oxide layer has a thickness of 10 to 150 Å.

8. A method for fabricating an isolation trench for a semiconductor device, comprising:
forming a trench in a selected region of a substrate;
forming an insulating layer on an inner surface of the trench, wherein the insulating layer includes a chemical vapor deposition (CVD) oxide layer containing Nitrogen;
forming a nitride liner on the insulating layer; and
filling the trench with a filler to form the isolation trench.

9. The method of claim 8, wherein the insulating layer further comprises forming a second oxide layer located between the N-containing CVD oxide layer and the inner surface of the isolation trench.

10. The method of claim 8, further comprising:
forming junction regions adjacent the isolation trench;
forming a gate oxide layer on the substrate; and
forming at least one gate electrode on the gate oxide layer and the trench isolation.

11. The method of claim 8, wherein the insulating layer is formed to a thickness of about 150 to 400 Å.

12. The method of claim 11, wherein the insulating layer has a thickness of about 180 to 250 Å.

13. The method of claim 8, wherein the CVD oxide layer is formed to a thickness of about 100 to 350 Å.

14. The method of claim 13, wherein formation of the CVD oxide layer includes heat treatment in atmosphere with a gas selected from the group consisting of N₂, NO, N₂O, NH₃, and a mixture gas thereof.

15. The method of claim 13, wherein formation of the CVD oxide layer includes a plasma processing in atmosphere with a gas selected from the group consisting of N₂, NO, N₂O, and NH₃, and a mixture gas thereof.

16. The method of claim 9, wherein the second oxide layer is formed to a thickness of about 10 to 150 Å.

17. A method for fabricating an isolation trench for a semiconductor device, comprising:
forming a trench in a selected region of a substrate;
forming an insulating layer on an inner surface of the trench to inhibit charge trapping at the inner surface of the trench, wherein the insulating layer includes a second oxide layer and a chemical vapor deposition (CVD) oxide layer containing Nitrogen;
forming a nitride liner on the insulating layer;
filling the trench with a filler to form the trench isolation;
forming junction regions adjacent the trench isolation;
forming a gate oxide layer on the substrate; and
forming at least one gate electrode on the gate oxide layer and the trench isolation.

18. The method of claim 17, wherein the insulating layer is formed to a thickness of about 180 to 250 Å.

19. The method of claim 17, wherein the CVD oxide layer is formed to a thickness of about 100 to 350 Å.

20. The method of claim 17, wherein the sidewall second layer is formed to a thickness of about 10 to 150 Å.
